(19) United States
(12) Patent Application Publication
(10) Pub. No.: US 2026/0198080 A1
(43) Pub. Date: Jul. 9, 2026

(54) GATE CONFIGURATIONS FOR BACKSIDE POWER DELIVERY

(71) Applicant: International Business Machines Corporation, Armonk, NY (US)

(72) Inventors: Lijuan Zou, Albany, NY (US); Tao Li, Slingerlands, NY (US); Ruilong Xie, Niskayuna, NY (US); Xiaoming Yang, Clifton Park, NY (US)

(21) Appl. No.: 19/009,523

(22) Filed: Jan. 3, 2025

(51) Int. Cl. H10D 84/85; H10D 84/01

(52) U.S. Cl. CPC H10D 84/851; H10D 84/0186; H10D 84/0188

(57) ABSTRACT

A semiconductor device includes a first source/drain region and a second source/drain region. The semiconductor device includes a first contact connecting the first source/drain region to a backside power distribution network and a second contact connecting the second source/drain region to a frontside interconnect layer. The semiconductor device further includes a first gate structure separated from a second gate structure by an isolation region, where the first gate structure is associated with the first source/drain region and the second gate structure is associated with the second source/drain region, and a gate jumper positioned below the isolation region and connected to the first gate structure and the second gate structure.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

### SUMMARY

Embodiments of the invention provide techniques for gate configurations for backside power delivery network (BSPDN) architectures.

In one embodiment, a semiconductor device includes a first source/drain region and a second source/drain region. The semiconductor device includes a first contact connecting the first source/drain region to a backside power distribution network and a second contact connecting the second source/drain region to a frontside interconnect layer. The semiconductor device further includes a first gate structure separated from a second gate structure by an isolation region, where the first gate structure is associated with the first source/drain region and the second gate structure is associated with the second source/drain region, and a gate jumper positioned below the isolation region and connected to the first gate structure and the second gate structure.

In another embodiment, a semiconductor device includes a first source/drain region and a second source/drain region, and a first contact connecting the first source/drain region to a backside power distribution network. The semiconductor device includes a second contact connecting the second source/drain region to a frontside interconnect layer, and a first gate structure separated from a second gate structure by an isolation region, where the first gate structure is associated with the first source/drain region and the second gate structure is associated with the second source/drain region. The semiconductor device further includes a via positioned below the isolation region and connected to the first gate structure and the second gate structure.

In yet another embodiment, a method includes forming an isolation region separating a first gate structure from a second gate structure, where the first gate structure is associated with a first source/drain region and the second gate structure is associated with a second source/drain region. The method includes forming a frontside source/drain contact for connecting the second source/drain region to a backside power distribution network to a frontside interconnect layer. The method further includes forming a conductive region below the isolation region, where the conductive region is connected to the first gate structure and the second gate structure, and forming a backside contact for connecting the first source/drain region to a backside power distribution network.

These and other features and advantages of embodiments described herein will become more apparent from the accompanying drawings and the following detailed description.

### BRIEF DESCRIPTION OF THE DRAWINGS

FIG. 1 depicts a top view of a semiconductor structure with lines Y1 and Y2 on which cross-sectional views of FIGS. 2A-12B are based.

FIG. 2A depicts a first cross-sectional view corresponding to line Y1 in FIG. 1 illustrating the semiconductor structure of FIG. 1 during an intermediate step of fabricating a nanosheet transistor structure, according to an illustrative embodiment.

FIG. 2B depicts a second cross-sectional view corresponding to line Y2 in FIG. 1 illustrating the semiconductor structure of FIG. 1 during the intermediate step of fabricating the nanosheet transistor structure, according to an illustrative embodiment.

FIG. 3A depicts a first cross-sectional view corresponding to line Y1 in FIG. 1 following formation of gate cut regions, according to an illustrative embodiment.

FIG. 3B depicts a second cross-sectional view corresponding to line Y2 in FIG. 1 following formation of the gate cut regions, according to an illustrative embodiment.

FIG. 4A depicts a first cross-sectional view corresponding to line Y1 in FIG. 1 following formation of frontside middle-of-line (MOL) contacts, according to an illustrative embodiment.

FIG. 4B depicts a second cross-sectional view corresponding to line Y2 in FIG. 1 following formation of the frontside MOL contacts, according to an illustrative embodiment.

FIG. 5A depicts a first cross-sectional view corresponding to line Y1 in FIG. 1 following frontside back-end-of-line (BEOL) interconnects formation and carrier wafer bonding, according to an illustrative embodiment.

FIG. 5B depicts a second cross-sectional view corresponding to line Y2 in FIG. 1 following the frontside BEOL interconnects formation and the carrier wafer bonding, according to an illustrative embodiment.

FIG. 6A depicts a first cross-sectional view corresponding to line Y1 in FIG. 1 following semiconductor substrate removal up to an etch stop layer, according to an illustrative embodiment.

FIG. 6B depicts a second cross-sectional view corresponding to line Y2 in FIG. 1 following the semiconductor substrate removal up to the etch stop layer, according to an illustrative embodiment.

FIG. 7A depicts a first cross-sectional view corresponding to line Y1 in FIG. 1 following removal of the etch stop layer, further semiconductor substrate removal, and formation of a capping layer, according to an illustrative embodiment.

FIG. 7B depicts a second cross-sectional view corresponding to line Y2 in FIG. 1 following the removal of the etch stop layer, the further semiconductor substrate removal, and the formation of the capping layer, according to an illustrative embodiment.

FIG. 8A depicts a first cross-sectional view corresponding to line Y1 in FIG. 1 following formation of an organic planarization layer, according to an illustrative embodiment.

FIG. 8B depicts a second cross-sectional view corresponding to line Y2 in FIG. 1 following the formation of the organic planarization layer, according to an illustrative embodiment.

FIG. 9A depicts a first cross-sectional view corresponding to line Y1 in FIG. 1 following removal of portions of a liner layer and an isolation region, and formation of a backside gate jumper, according to an illustrative embodiment.

FIG. 9B depicts a second cross-sectional view corresponding to line Y2 in FIG. 1 following the removal of the portions of the liner layer and the isolation region, and the formation of the backside gate jumper, according to an illustrative embodiment.

FIG. 10A depicts a first cross-sectional view corresponding to line Y1 in FIG. 1 following recessing of the backside gate jumper, formation of a dielectric region, removal of the capping layer and remaining semiconductor substrate, and formation of a backside ILD layer, according to an illustrative embodiment.

FIG. 10B depicts a second cross-sectional view corresponding to line Y2 in FIG. 1 following the recessing of the backside gate jumper, the formation of the dielectric region, the removal of the capping layer and the remaining semiconductor substrate, and the formation of the backside ILD layer, according to an illustrative embodiment.

FIG. 11A depicts a first cross-sectional view corresponding to line Y1 in FIG. 1 following backside source/drain contact formation, according to an illustrative embodiment.

FIG. 11B depicts a second cross-sectional view corresponding to line Y2 in FIG. 1 following the backside source/drain contact formation, according to an illustrative embodiment.

FIG. 12A depicts a first cross-sectional view corresponding to line Y1 in FIG. 1 following formation of a backside via layer, a buried power rail (BPR) layer, a signal line layer, and a BSPDN layer, according to an illustrative embodiment.

FIG. 12B depicts a second cross-sectional view corresponding to line Y2 in FIG. 1 following the formation of the backside via layer, the BPR layer, the signal line layer, and the BSPDN layer, according to an illustrative embodiment.

FIG. 13 depicts a top view of a semiconductor structure indicating Y1 and Y2 cross-section locations on which the cross-sectional views of FIGS. 14A-17B are based, in accordance with an alternative illustrative embodiment starting from FIGS. 9A and 9B.

FIG. 14A depicts a first cross-sectional view corresponding to line Y1 in FIG. 13 following formation of a backside via, according to an illustrative embodiment.

FIG. 14B depicts a second cross-sectional view corresponding to line Y2 in FIG. 13 following the formation of the backside via, according to an illustrative embodiment.

FIG. 15A depicts a first cross-sectional view corresponding to line Y1 in FIG. 13 following removal of a capping layer and semiconductor substrate, and formation of a backside ILD layer, according to an illustrative embodiment.

FIG. 15B depicts a second cross-sectional view corresponding to line Y2 in FIG. 13 following the removal of the capping layer and the semiconductor substrate, and the formation of the backside ILD layer, according to an illustrative embodiment.

FIG. 16A depicts a first cross-sectional view corresponding to line Y1 in FIG. 13 following backside source/drain contact formation and backside gate contact formation, according to an illustrative embodiment.

FIG. 16B depicts a second cross-sectional view corresponding to line Y2 in FIG. 13 following the backside source/drain contact formation and the backside gate contact formation, according to an illustrative embodiment.

FIG. 17A depicts a first cross-sectional view corresponding to line Y1 in FIG. 13 following backside via layer formation, BPR layer formation, signal line layer formation, and a BSPDN layer formation, according to an illustrative embodiment.

FIG. 17B depicts a second cross-sectional view corresponding to line Y2 in FIG. 13 following the backside via layer formation, the BPR layer formation, the signal line layer formation, and the BSPDN layer formation, according to an illustrative embodiment.

### DETAILED DESCRIPTION

Illustrative embodiments of the invention may be described herein in the context of illustrative methods for forming gate structure configurations for backside power delivery, along with illustrative apparatus, systems, and devices formed using such methods. However, it is to be understood that embodiments of the invention are not limited to the illustrative methods, apparatus, systems, and devices but instead are more broadly applicable to other suitable methods, apparatus, systems, and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

A FET is a transistor having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the size of FETs. One technique is through the use of fin-shaped channels in fin field-effect transistors (FinFET). Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures, the gate can more effectively control the channel, as the gate extends over more than one side or surface of the channel. In some FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheets may be two-dimensional nanostructures, such as sheets having a thickness range on the order of 1 to 20 nanometers (nm). Nanosheets and nanowires are viable options for scaling to 7 nm and beyond. A general process flow for forming a nanosheet stack involves selectively removing sacrificial layers, which may be formed of silicon germanium (SiGe), between sheets of channel material, which may be formed of silicon (Si).

For continued scaling (e.g., to 2.5 nm and beyond), next-generation stacked FET devices may be used. Next-generation stacked FET devices provide a complex gate-all-around (GAA) structure. Conventional GAA FETs, such as nanosheet FETs, may stack multiple p-type nanowires or nanosheets on top of each other in one device, and may stack multiple n-type nanowires or nanosheets on top of each other in another device. Next-generation stacked FET structures provide improved track height scaling, leading to structural gains (e.g., such as 30-40% structural gains for different types of devices, such as logic devices, static random-access memory (SRAM) devices, etc.). In next-generation stacked FET structures, n-type and p-type nanowires or nanosheets are stacked on each other, eliminating n-to-p separation bottlenecks and reducing the device area footprint. There is, however, a continued desire for further scaling and reducing the size of FETs.

As discussed above, various techniques may be used to reduce the size of FETs, including using fin-shaped channels in FinFET devices, using stacked nanosheet channels formed over a semiconductor substrate, and using next-generation stacked FET devices.

Although embodiments described herein are discussed in connection with nanosheet stacks, the embodiments are not necessarily limited thereto, and may similarly apply to nanowire stacks.

The concept of BPR refers to power rails that are buried below the BEOL metal stack, usually in-level with the transistor fins themselves. BSPDN, or grids, enable scaling beyond 5 nm with the backside being below the transistor substrate. The BPR technology enables the freeing up of resources for the dense logic connections often limiting modern processor performance. Further scaling of a standard logic cell is enabled by removing the overhead in the area occupied by the power rails. Finally, thicker low-resistance power rails are allowed, which enable lower voltage (IR) drops.

Conventional techniques typically form semiconductor structures having a large gate size that overlaps with source/drain regions and source/drain contacts, which leads to parasitic capacitance between these elements. Such techniques can result in frontside MOL routing congestion, making it challenging to efficiently interconnect various components of the semiconductor structure. Moreover, the substantial gate metal content contributes to increased parasitic capacitance, negatively impacting device performance.

Illustrative embodiments described herein can mitigate these issues by introducing a shared backside conductive element (e.g., a gate jumper or a backside via), which can effectively reduce routing congestion, while reducing the amount of gate material. Such embodiments simplify the interconnection process and effectively reduce parasitic capacitance, thereby leading to improved device performance.

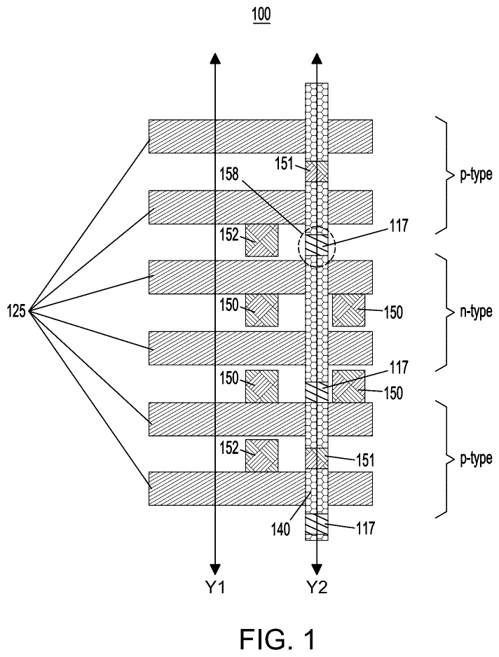

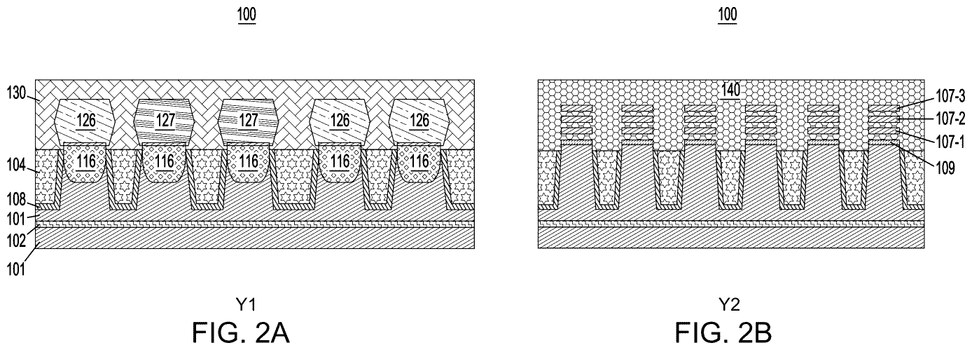

Referring to FIG. 1 and to the cross-sectional views in FIGS. 2A and 2B, which respectively correspond to the lines Y1 and Y2 in FIG. 1, a semiconductor structure 100 includes active areas 125. The active areas 125 may be associated with a first plurality of source/drain regions 127 having a first doping type (e.g., n-type) and a second plurality of source/drain regions 126 having a second doping type (e.g., p-type).

The semiconductor structure 100 includes six stacks of channel layers 107-1, 107-2, and 107-3 (collectively “channel layers 107”) over a semiconductor substrate 101. In an illustrative embodiment, the channel layers 107 comprise silicon. The stacked structure also includes a bottom dielectric isolation (BDI) layer 109. The BDI layer 109 may comprise, for example, silicon oxide (SiOₓ) (where x is for example, 2, 1.99 or 2.01), silicon oxycarbide (SiOC), silicon nitride (SiN), silicon oxynitride (SiON), silicon-carbon-nitride (SiCN), boron nitride (BN), silicon boron nitride (SiBN), silicoboron carbonitride (SiBCN), silicon oxycarbonitride (SiOCN) and combinations thereof.

While three channel layers 107 are shown, the embodiments described herein are not necessarily limited to the shown number of channel layers 107. There may be more or less channel layers depending on design constraints, for example.

In some embodiments, the channel layers 107 and BDI layer 109 are epitaxially grown on the semiconductor substrate 101. The terms “epitaxial growth and/or deposition” and “epitaxially formed and/or grown,” mean the growth of a semiconductor material (crystalline material) on a deposition surface of another semiconductor material (crystalline material), in which the semiconductor material being grown (crystalline over layer) has substantially the same crystalline characteristics as the semiconductor material of the deposition surface (seed material). In an epitaxial deposition process, the chemical reactants provided by the source gases are controlled, and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed.

The semiconductor substrate 101 may be formed of any suitable semiconductor structure, including various silicon-containing materials including but not limited to Si, SiGe, silicon germanium carbide (SiGeC), silicon carbide (SiC) and multi-layers thereof. Although silicon is the predominantly used semiconductor material in wafer fabrication, alternative semiconductor materials can be employed as additional layers, such as, but not limited to, germanium (Ge), gallium arsenide (GaAs), gallium nitride (GaN), SiGe, cadmium telluride (CdTe), and zinc selenide (ZnSe).

As used herein, “frontside” or “first side” refers to a side on top of the semiconductor substrate 101 and/or in front of, on top of or in an upward direction from the stacked gate and channel layers of the transistors in the orientation shown in the cross-sectional figures. As used herein, “backside” or “second side” refers to a side below the semiconductor substrate 101 and/or behind, below, or in a downward direction from the stacked gate and channel layers of the transistors in the orientation shown in the cross-sectional figures (for example, opposite the “frontside”).

An etch stop layer 102 is formed in the semiconductor substrate 101. The etch stop layer 102 may comprise a buried oxide (BOX) layer or SiGe, or another suitable material such as a III-V semiconductor epitaxial layer.

Isolation regions 104 (for example, shallow trench isolation (STI) regions) comprising dielectric material fill in recessed portions of the semiconductor substrate 101 between stacks of the channel layers 107. A corresponding liner layer 108 is also formed between the isolation regions 104 and the semiconductor substrate 101. The liner layer 108 may be formed of SiN or another suitable material such as SiBCN, SiCOH, SiNCH, etc. The dielectric material may comprise, for example, SiN, SiON, SiCN, BN, SiBN, SiBCN, SiOCN, and combinations thereof.

The source/drain regions 126 and 127, in some embodiments, can be grown between the stacks of the channel layers 107 using an epitaxial growth process. For example, the epitaxial growth process may include rapid thermal chemical vapor deposition (RTCVD) epitaxial growth using SiH₄, SiH₂Cl₂, GeH₄, CH₃SiH₃, B₂H₆, PF₃, and/or H₂ gases. In the case of n-type FETS (nFETs), the source/drain regions 126 and 127 can comprise silicon doped with n-type dopants including, for example, phosphorus (P), arsenic (As) and antimony (Sb). In the case of p-type FETS (pFETs), the source/drain regions 126 and 127 can comprise silicon doped with p-type dopants including, for example, boron (B), boron fluoride (BF₂), gallium (Ga), indium (In), and thallium (Tl).

An ILD layer 130 is deposited to fill in portions on and around the source/drain regions 126 and 127. The ILD layer 130 may comprise, for example, SiOx, SiOC, SiOCN or some other dielectric. Sacrificial placeholders 116 are formed below the source/drain regions 126 and 127. The sacrificial placeholder 116 may comprise, for example, SiGe.

The gate structures 140 may include gate and dielectric portions. In illustrative embodiments, each gate structure 140 includes a gate dielectric layer such as, for example, a high-K dielectric layer such as, but not limited to, HfO₂ (hafnium oxide), ZrO₂ (zirconium dioxide), hafnium zirconium oxide, Al₂O₃ (aluminum oxide), and Ta₂O₅ (tantalum oxide). Examples of high-k materials also include, but are not limited to, metal oxides such as hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate.

According to an embodiment, the gate structures 140 each include a metal gate portion including a work-function metal (WFM) layer, including but not necessarily limited to, for a pFET, titanium nitride (TiN), tantalum nitride (TaN) or ruthenium (Ru), and for an nFET, TiN, titanium aluminum nitride (TiAlN), titanium aluminum carbon nitride (TiAlCN), titanium aluminum carbide (TiAlC), tantalum aluminum carbide (TaAlC), tantalum aluminum carbon nitride (TaAlCN) or lanthanum (La) doped TiN, TaN, which can be deposited on the gate dielectric layer. The metal gate portions can also each further include a gate metal layer such as, but not limited to, metals such as, for example, tungsten, cobalt, zirconium, tantalum, titanium, aluminum, ruthenium, copper, metal carbides, metal nitrides, transition metal aluminides, tantalum carbide, titanium carbide, tantalum magnesium carbide, or combinations thereof deposited on the WFM layer and the gate dielectric layer. It should be appreciated that various other materials may be used for the metal gate portions as desired.

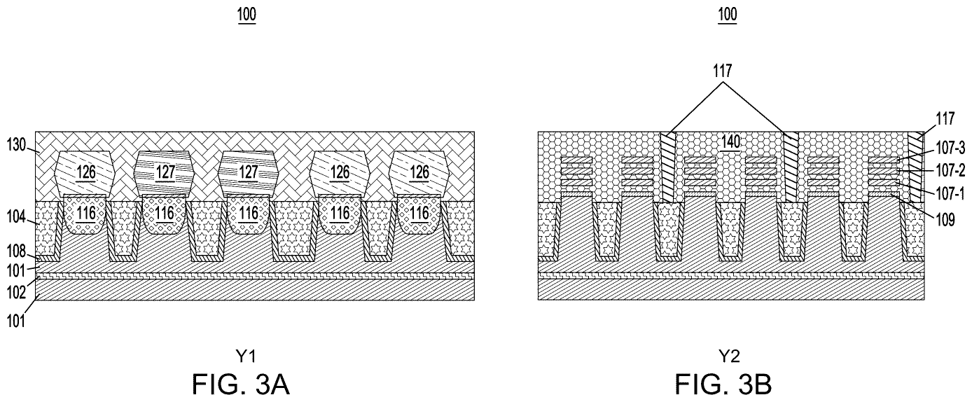

FIGS. 3A and 3B depict cross-sectional views respectively corresponding to lines Y1 and Y2 in FIG. 1 following formation of gate cut regions 117, according to an illustrative embodiment. Portions of gate structures 140 between the nanosheet stacks comprising the channel layers 107 and the gate structures 140 is removed down to corresponding ones of the isolation regions 104. In some embodiments, parts of the exposed portion of the isolation region 104 may also be removed. Dielectric material is deposited in the parts of the gate structures 140 that were removed to form the gate cut regions 117. The portions of the gate structures 140 can be etched using, for example, reactive ion etch (RIE). The exposed portion of the isolation region 104 may be etched using, for example, RIE. The dielectric material of the gate cut regions 117 is deposited using deposition techniques such as chemical vapor deposition (CVD), plasma-enhanced CVD (PECVD), radio-frequency CVD (RFCVD), physical vapor deposition (PVD), atomic layer deposition (ALD), molecular beam deposition (MBD), pulsed laser deposition (PLD), and/or liquid source misted chemical deposition (LSMCD), followed by a planarization step such as a chemical mechanical planarization (CMP) process to remove excess portions of the dielectric material deposited on top of the gate structures 140. The dielectric material of the gate cut regions 117 may comprise, but is not necessarily limited to, SiN, SiC, SiON, SiOC, SiCN, BN, SiBN, SiBCN, SiOCN, SiOₓ or some other dielectric. In the example shown in FIG. 3B, three gate cut regions 117 are formed.

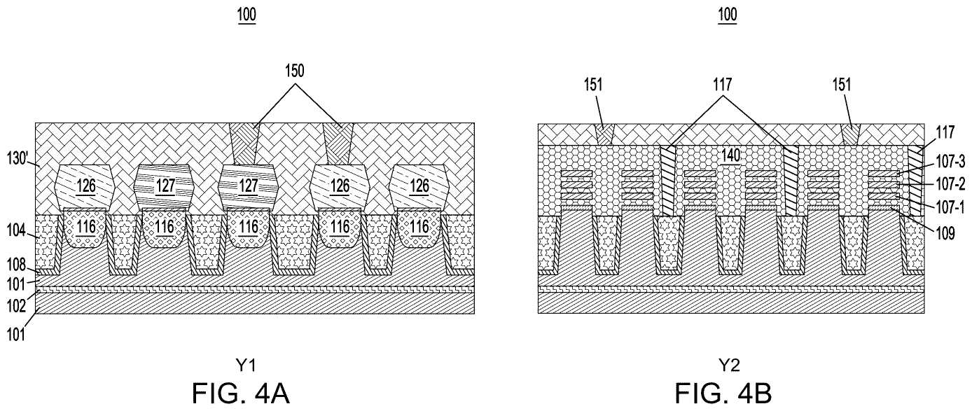

FIGS. 4A and 4B depict cross-sectional views respectively corresponding to lines Y1 and Y2 in FIG. 1 following formation of MOL contacts, according to an illustrative embodiment. The MOL contacts include frontside source/drain contacts 150 and frontside gate contacts 151.

Additional ILD material is deposited on the ILD layer 130, thereby forming ILD layer 130′. The frontside source/drain contacts 150 are formed in the ILD layer 130′ to contact respective top surfaces of the source/drain regions 126 and 127. To form the frontside source/drain contacts 150, openings are created through portions of the ILD layer 130′, exposing the corresponding portions of the source/drain regions 126 and 127 on which the frontside source/drain contacts 150 are to be formed. According to an embodiment, masks are formed on parts of the ILD layer 130′, and exposed portions of the ILD layer 130 corresponding to where the openings are to be formed are removed using, for example, a dry etching process using a RIE or ion beam etch (IBE) process, a wet chemical etch process, or a combination of these etching processes. A dry etch may be performed using a plasma. Such wet or dry etch processes include, for example, IBE by Ar/CHF3 based chemistry.

Metal layers can then be deposited in the openings to form the frontside source/drain contacts 150. The metal layers may include a silicide layer, such as Ni, Ti, NiPt, etc., a metal adhesion layer, such as TiN, and a conductive metal fill layer, such as W, Al, Co, Ru, etc., and can be deposited using, for example, a deposition technique such as CVD, PECVD, RFCVD, PVD, ALD, MBD, PLD, LSMCD, sputtering, and/or plating, followed by planarization processes such as CMP to remove excess portions of the metal layers from on top of the ILD layer 130′.

The process and materials used for forming the frontside gate contacts 151 are similar to those used for forming the frontside source/drain contacts 150.

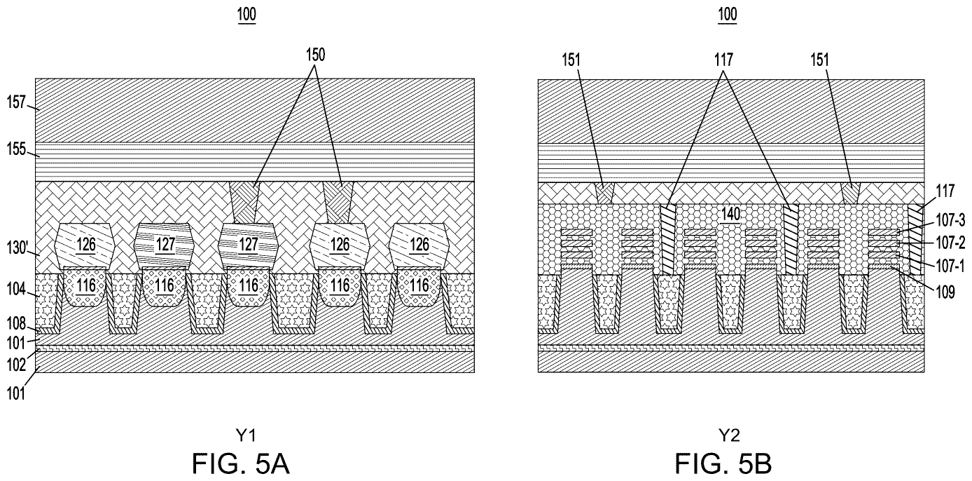

FIGS. 5A and 5B depict cross-sectional views respectively corresponding to lines Y1 and Y2 in FIG. 1 following formation of frontside BEOL interconnects 155 and carrier wafer 157. The frontside BEOL interconnects 155 are formed on the ILD layer 130′ and include various BEOL interconnect structures. The carrier wafer 157 may be formed of materials similar to those used in the semiconductor substrate 101 and can be formed over the frontside BEOL interconnects 155 using a wafer bonding process, such as dielectric-to-dielectric bonding.

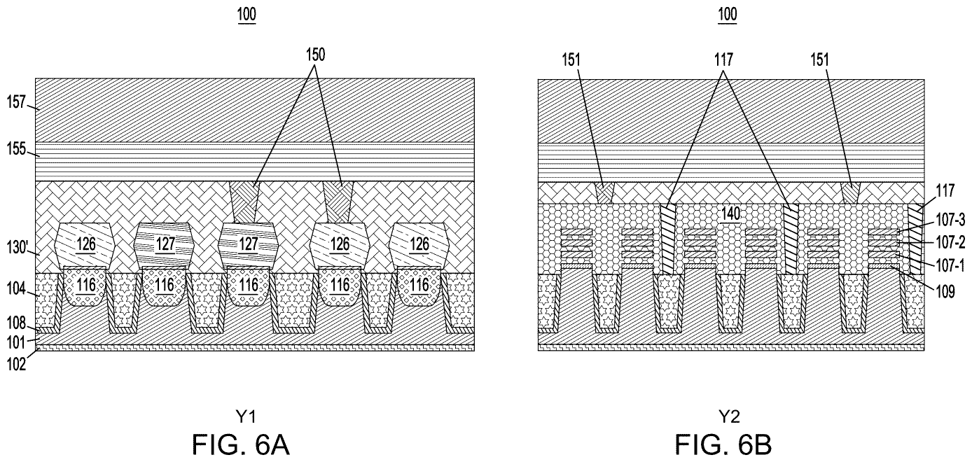

Referring to FIGS. 6A-6B, using the carrier wafer 157, the semiconductor structure 100 may be “flipped” (for example, rotated 180 degrees) so that the structure is inverted. In addition, the semiconductor substrate 101 is removed from the backside of the semiconductor structure 100 stopping at the etch stop layer 102. For example, the semiconductor substrate 101 can be selectively etched with an etchant that selectively etches silicon with respect to a material of the etch stop layer 102.

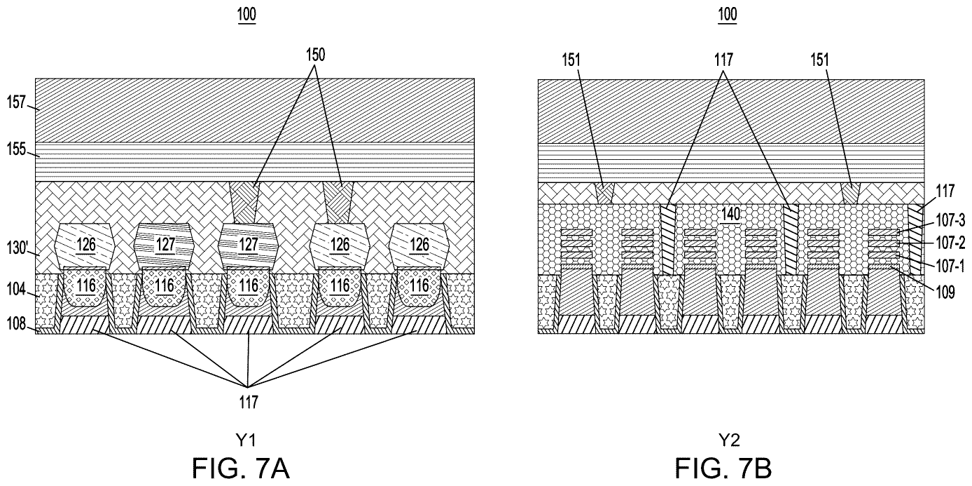

Referring to FIGS. 7A-7B, the etch stop layer 102 and portions of the remaining semiconductor substrate 101 are removed. The portions of the remaining semiconductor substrate 101 are removed above a level corresponding to the bottom surfaces of the isolation regions 104 and below a level of the bottom surfaces of the sacrificial placeholders 116, for example. The etching processes for removal of the etch stop layer 102 include but are not limited to IBE using Ar/CHF3 based chemistry. Etchants for removing the semiconductor substrate 101 include, for example, potassium hydroxide (KOH) and trimethylaluminum (TMA).

A capping layer 118 is formed below the remaining portions of the semiconductor substrate 101 and between the isolation regions 104. The capping layer 118 may comprise a suitable capping material (for example, silicon carbide (SiC) or silicon nitride (SiN)).

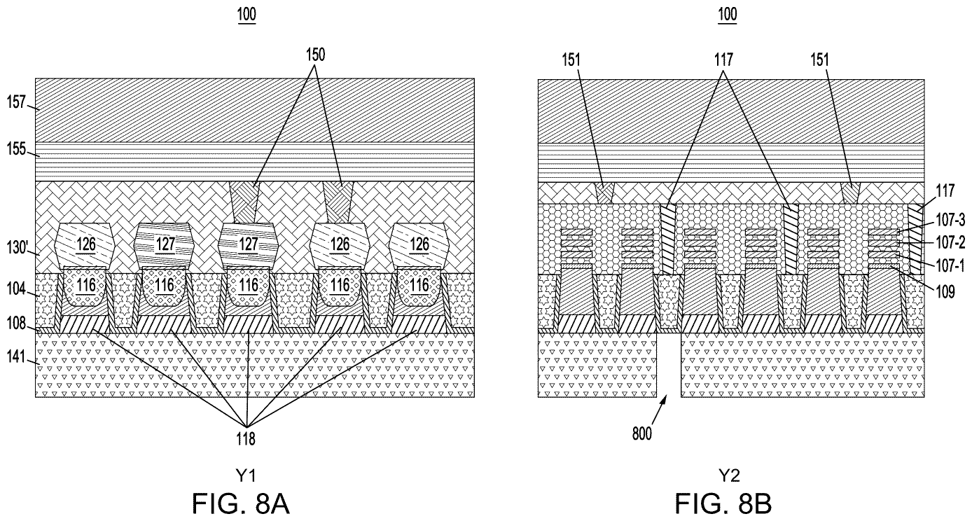

FIGS. 8A-8B depict cross-sectional views respectively corresponding to lines Y1 and Y2 in FIG. 1 following formation of an organic planarization layer (OPL) 141 on the bottom surface of the semiconductor structure 100. In some embodiments, the OPL 141 can be formed of an organic polymer such as carbon, hydrogen, and/or nitrogen, for example. The OPL 141 is then patterned to form an opening 800 that exposes a portion of the liner layer 108 below one of the isolation regions 104.

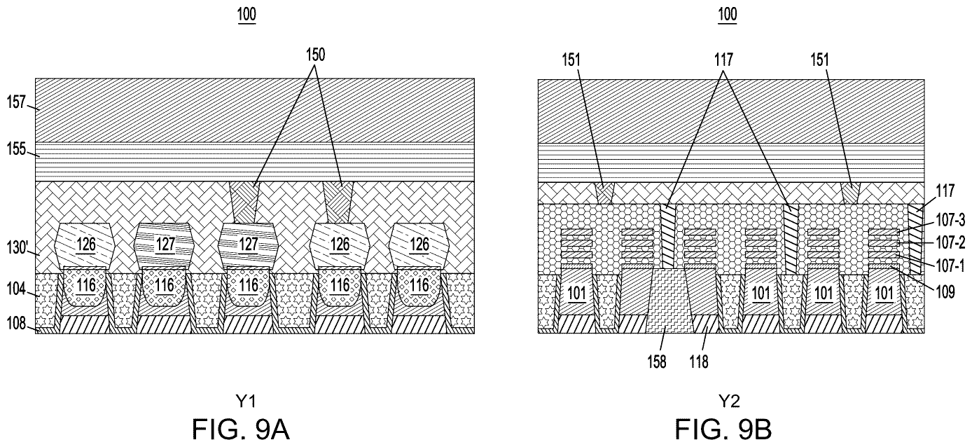

FIGS. 9A-9B depict cross-sectional views respectively corresponding to lines Y1 and Y2 in FIG. 1 following removal of the liner layer 108 and the isolation region 104 corresponding to the opening 800, and formation of a backside gate jumper 158. In some embodiments, the liner layer 108 may be removed using a self-aligned etching process, followed by an etching process to remove the isolation region 104. The etching processes used to remove the portions of the liner layer 108 and the isolation region 104 can include a dry etching process (such as RIE or IBE), a wet chemical etching process, or a combination of these etching processes.

An ashing process is performed that strips the OPL 141 using, for example, oxygen plasma, nitrogen/hydrogen plasma, or other carbon strip process. Following the removal of the OPL 141, the backside gate jumper 158 is formed by filling and planarizing of conductive material. The conductive material of the backside gate jumper 158 may be any suitable conductive material, such as those used to form the frontside source/drain contacts 150 and/or the frontside gate contacts 151. The backside gate jumper 158 contacts bottom surfaces of one of the gate cut regions 117 and portions of the gate structures 140 on either side of the gate cut region 117. A planarization process (e.g., CMP) can be performed to remove excess conductive material from the backside of the semiconductor structure 100.

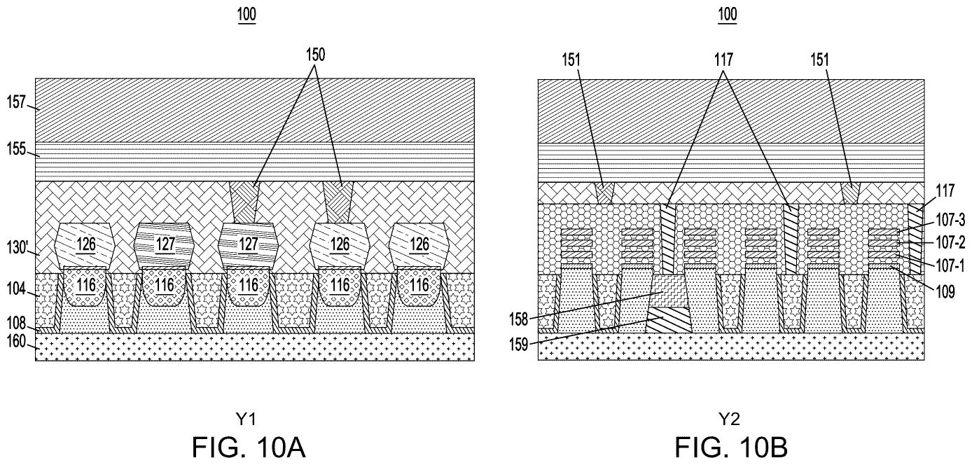

FIGS. 10A-10B depict cross-sectional views respectively corresponding to lines Y1 and Y2 in FIG. 1 following recessing of the backside gate jumper 158, formation of a dielectric region 159, removal of the capping layer 118 and remaining semiconductor substrate 101, and formation of a backside ILD layer 160. The backside gate jumper 158 is partially removed using one or more etching processes such as wet and/or dry etching processes, and the resulting vacant area is filled with a dielectric material to form the dielectric region 159. The dielectric region 159 may be formed using similar techniques and materials as the gate cut regions 117, followed by a planarization process (e.g., CMP) to remove excess portions of the dielectric material.

The remaining portions of the capping layer 118 and the semiconductor substrate 101 are removed using, for example, one or more etching processes such as wet and/or dry etching processes.

The backside ILD layer 160 is formed using deposition techniques such as CVD, PECVD, RFCVD, PVD, ALD, MBD, PLD, and/or LSMCD. The backside ILD layer 160 may comprise, for example, SiOₓ, SiOC, SiOCN or some other dielectric.

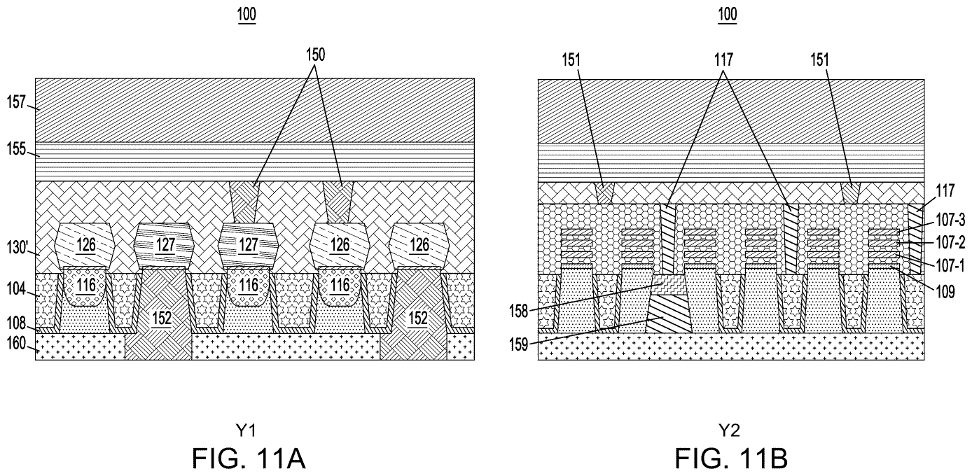

FIGS. 11A-11B depict cross-sectional views respectively corresponding to lines Y1 and Y2 in FIG. 1 following formation of backside source/drain contacts 152. In the example shown in FIG. 11A, two backside source/drain contacts 152 are respectively formed below one of the source/drain regions 126 and one of the source/drain regions 127. In forming the backside source/drain contacts 152, openings are formed through a portion of the backside ILD layer 160. The openings expose the corresponding portions of the sacrificial placeholders 116. According to an embodiment, one or more masks are formed on parts of the backside ILD layer 160, and exposed portions of the backside ILD layer 160 corresponding to where the openings are to be formed are removed. The exposed portions of the sacrificial placeholders 116 are then removed to expose the bottom surfaces of the corresponding source/drain region 126 and source/drain region 127. The portions of the backside ILD layer 160 and the sacrificial placeholders 116 can each be removed using one or more etching processes such as wet and/or dry etching processes.

The backside source/drain contacts 152 are formed by filling and planarizing of contact material. The contact material of the backside source/drain contact 152 may be similar to that of the frontside source/drain contacts 150 and/or the frontside gate contacts 151, for example.

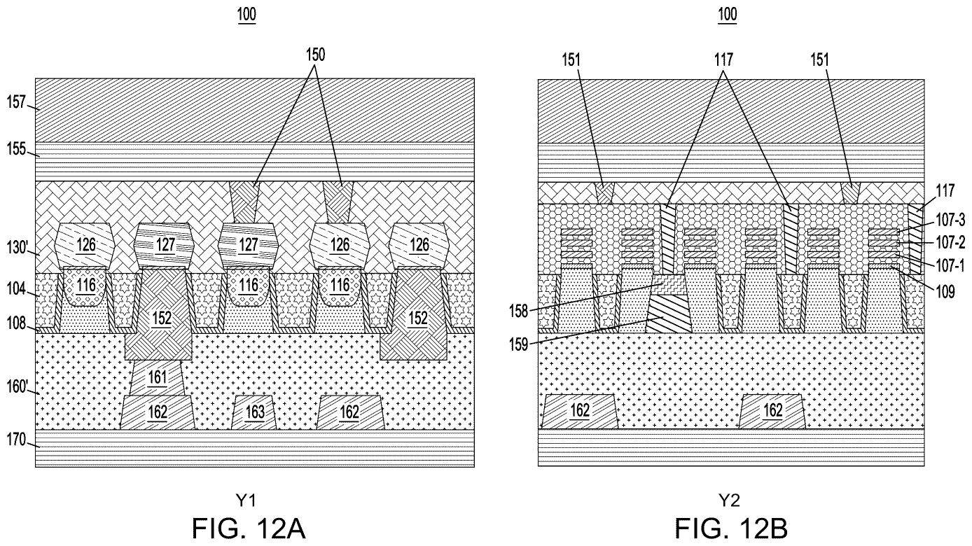

FIGS. 12A-12B depict cross-sectional views respectively corresponding to lines Y1 and Y2 in FIG. 1, of the semiconductor structure 100 following formation of a backside via layer 161, a BPR layer 162, a signal line layer 163, and a BSPDN layer 170. For example, one or more additional layers of dielectric material can be deposited to the backside ILD layer 160, thereby forming backside ILD layer 160′. The backside via layer 161, the BPR layer 162, and the signal line layer 163 can be formed in the backside ILD layer 160′ using similar techniques and materials as the frontside source/drain contacts 150 and/or the frontside gate contacts 151. In this example, the backside via layer 161 is connected to one of the backside source/drain contacts 152 and a portion of the BPR layer 162.

The BSPDN layer 170 is formed on the backside ILD layer 160′, the BPR layer 162, and the signal line layer 163. In some embodiments, the BSPDN layer 170 can include various backside power delivery network structures such as, but not limited to, interconnects in a power supply path from voltage regulator modules (VRMs) to circuits. The interconnects can comprise, for example, power and ground planes in circuit boards, cables, connectors, and capacitors associated with a power supply. Backside power delivery prevents BEOL routing congestion, resulting in power performance benefits. In some embodiments, the BSPDN layer 170 can alternatively or additionally be used for routing of signals (e.g., associated with signal line layer 163), including power and/or clock signals, as non-limiting examples.

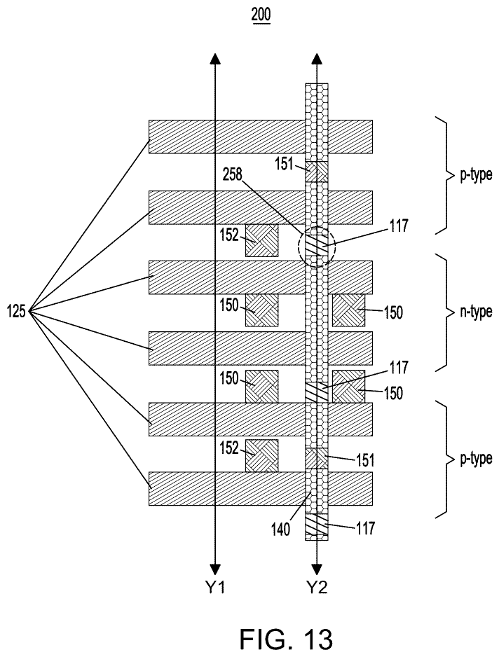

FIGS. 13-17 show a semiconductor structure 200 in accordance with an alternative illustrative embodiment starting from FIGS. 9A and 9B of the semiconductor structure 100 following the formation of the OPL 141, according to an illustrative alternative embodiment.

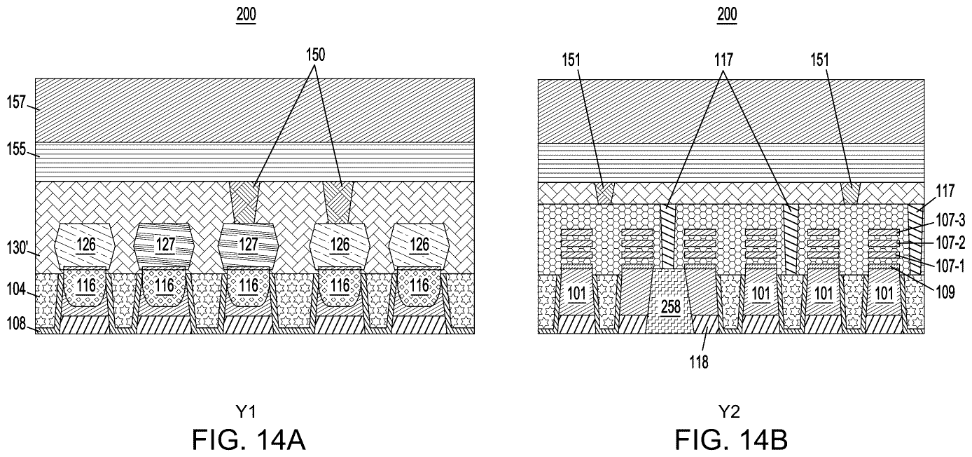

Referring to FIG. 13 and the cross-sectional views in FIGS. 14A and 14B respectively corresponding to lines Y1 and Y2 in FIG. 13, the semiconductor structure 200 is shown following removal of the liner layer 108 and the isolation region 104 corresponding to the opening 800 (shown in FIG. 8), and formation of a backside via 258. The removal of the liner layer 108, the isolation region 104 corresponding to the opening 800, and the OPL layer can be removed using similar techniques as described in conjunction with FIGS. 9A and 9B, for example. The backside via 258 can be formed using similar techniques and materials as the backside gate jumper 158, for example. The backside via 258 contacts bottom surfaces of one of the gate cut regions 117 and portions of the gate structures 140 on either side of the gate cut region 117.

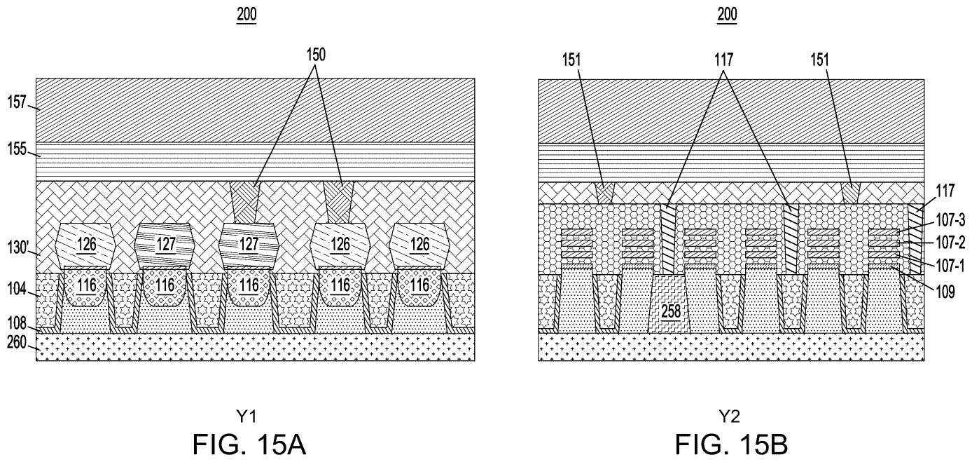

FIGS. 15A-15B depict cross-sectional views respectively corresponding to lines Y1 and Y2 in FIG. 13 following removal of the capping layer 118 and remaining semiconductor substrate 101, and formation of backside ILD layer 260. The remaining portions of the capping layer 118 and the semiconductor substrate 101 are removed using, for example, one or more etching processes such as wet and/or dry etching processes. The backside ILD layer 260 surrounds the backside via 258 and is formed using deposition techniques such as CVD, PECVD, RFCVD, PVD, ALD, MBD, PLD, and/or LSMCD. The backside ILD layer 260 may comprise, for example, SiOₓ, SiOC, SiOCN or some other dielectric.

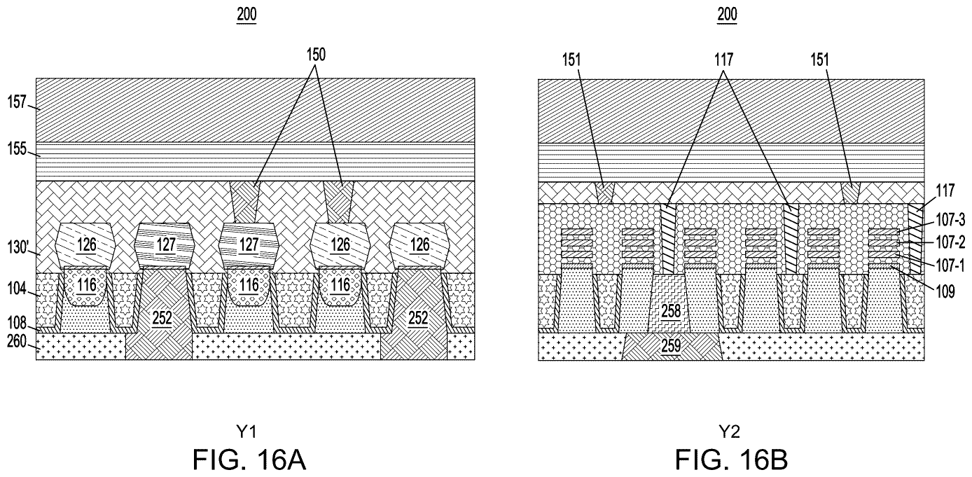

FIGS. 16A-16B depict cross-sectional views respectively corresponding to lines Y1 and Y2 in FIG. 13 following formation of backside source/drain contacts 252 and backside gate contact 259. In the example shown in FIG. 16A, two backside source/drain contacts 252 are respectively formed below one of the source/drain regions 126 and one of the source/drain regions 127. The backside source/drain contacts 252 and the backside gate contact 259 can be formed using similar techniques and materials as the backside source/drain contacts 152. The backside gate contact 259 contacts a bottom surface of the backside via 258.

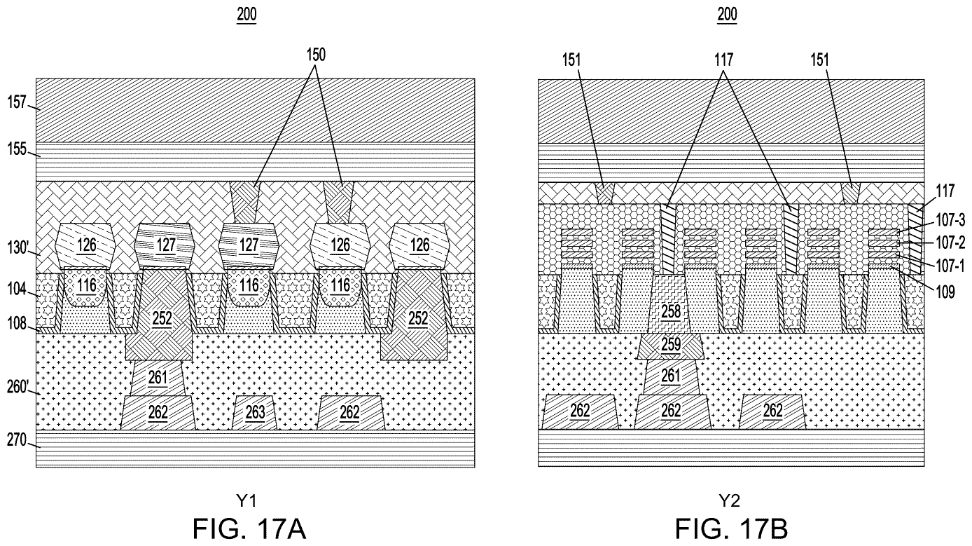

FIGS. 17A-17B depict cross-sectional views respectively corresponding to lines Y1 and Y2 in FIG. 1, of the semiconductor structure 100 following formation of a backside via layer 261, a BPR layer 262, a signal line layer 263, and a BSPDN layer 270. For example, one or more additional layers of dielectric material can be deposited to the backside ILD layer 260, thereby forming backside ILD layer 260′. The backside via layer 261, the BPR layer 262, and the signal line layer 263 can be formed in the backside ILD layer 260′ using similar techniques and materials as the frontside source/drain contacts 150 and/or the frontside gate contacts 151. In this example, respective top portions of the backside via layer 261 are connected to one of the backside source/drain contacts 252 and the backside gate contact 259. The bottom portions of the backside via layer 261 are connected to the BPR layer 262.

The BSPDN layer 270 is formed on the backside ILD layer 260′, the BPR layer 262, and the signal line layer 263. In some embodiments, the BSPDN layer 270 can include various backside power delivery network structures as the BSPDN layer 170.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETs, and/or FinFETs. By way of non-limiting example, the semiconductor devices can include, but are not limited to, CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case, the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

In one embodiment, a semiconductor device includes a first source/drain region and a second source/drain region. The semiconductor device includes a first contact connecting the first source/drain region to a backside power distribution network and a second contact connecting the second source/drain region to a frontside interconnect layer. The semiconductor device further includes a first gate structure separated from a second gate structure by an isolation region, where the first gate structure is associated with the first source/drain region and the second gate structure is associated with the second source/drain region, and a gate jumper positioned below the isolation region and connected to the first gate structure and the second gate structure.

In embodiments, the first contact may include a backside source/drain contact.

In embodiments, the second contact may include a frontside source/drain contact.

In embodiments, the gate jumper may include a conductive material.

In embodiments, the first source/drain region and the second source/drain region may be different types of source/drain regions.

In embodiments, the different types of source/drain regions comprise an n-type source/drain region and a p-type source/drain region.

In embodiments, the semiconductor device may further include a dielectric region positioned below the gate jumper.

In embodiments, the semiconductor device may further include a backside interlayer dielectric layer surrounding side surfaces of the gate jumper and positioned below and side and bottom surfaces of the dielectric region.

In another embodiment, a semiconductor device includes a first source/drain region and a second source/drain region, and a first contact connecting the first source/drain region to a backside power distribution network. The semiconductor device includes a second contact connecting the second source/drain region to a frontside interconnect layer, and a first gate structure separated from a second gate structure by an isolation region, where the first gate structure is associated with the first source/drain region and the second gate structure is associated with the second source/drain region. The semiconductor device further includes a via positioned below the isolation region and connected to the first gate structure and the second gate structure.

In embodiments, the semiconductor device may further include a backside gate contact positioned below the via.

In embodiments, the backside gate contact may connect the first gate structure and the second gate structure to the backside power delivery network.

In embodiments, the first contact may include a backside source/drain contact, and the second contact may include a frontside source/drain contact.

In embodiments, the via may include a conductive material.

In embodiments, the first source/drain region and the second source/drain region may be different types of source/drain regions.

In embodiments, the different types of source/drain regions may include an n-type source/drain region and a p-type source/drain region.

In embodiments, the semiconductor device may include a backside interlayer dielectric layer surrounding side surfaces of the via.

In yet another embodiment, a method includes forming an isolation region separating a first gate structure from a second gate structure, where the first gate structure is associated with a first source/drain region and the second gate structure is associated with a second source/drain region. The method includes forming a frontside source/drain contact for connecting the second source/drain region to a backside power distribution network to a frontside interconnect layer. The method further includes forming a conductive region below the isolation region, where the conductive region is connected to the first gate structure and the second gate structure, and forming a backside contact for connecting the first source/drain region to a backside power distribution network.

In embodiments, the method may further include forming a dielectric region positioned below the conductive region, wherein the conductive region corresponds to a gate jumper.

In embodiments, the method may further include forming a backside gate contact connected to the conductive region, wherein the conductive region corresponds to a via.

In embodiments, the first source/drain region and the second source/drain region are different types of source/drain regions.

The above-described embodiments advantageously implement a backside gate jumper or a backside via that can significantly reduce frontside MOL routing congestion and reduce the amount of gate material used. Such embodiments can effectively reduce parasitic capacitance, thereby improving device performance for BSPDN architectures.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times, and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a first source/drain region and a second source/drain region;
a first contact connecting the first source/drain region to a backside power delivery network;
a second contact connecting the second source/drain region to a frontside interconnect layer;
a first gate structure separated from a second gate structure by an isolation region, wherein the first gate structure is associated with the first source/drain region and the second gate structure is associated with the second source/drain region; and
a gate jumper positioned below the isolation region and connected to the first gate structure and the second gate structure.

2. The semiconductor device of claim 1, wherein the first contact comprises a backside source/drain contact.

3. The semiconductor device of claim 1, wherein the second contact comprises a frontside source/drain contact.

4. The semiconductor device of claim 1, wherein the gate jumper comprises a conductive material.

5. The semiconductor device of claim 1, wherein the first source/drain region and the second source/drain region are different types of source/drain regions.

6. The semiconductor device of claim 5, wherein the different types of source/drain regions comprise an n-type source/drain region and a p-type source/drain region.

7. The semiconductor device of claim 1, further comprising:
a dielectric region positioned below the gate jumper.

8. The semiconductor device of claim 7, further comprising:
a backside interlayer dielectric layer surrounding side surfaces of the gate jumper and positioned below and side and bottom surfaces of the dielectric region.

9. A semiconductor device comprising:
a first source/drain region and a second source/drain region;
a first contact connecting the first source/drain region to a backside power delivery network;
a second contact connecting the second source/drain region to a frontside interconnect layer;
a first gate structure separated from a second gate structure by an isolation region, wherein the first gate structure is associated with the first source/drain region and the second gate structure is associated with the second source/drain region; and
a via positioned below the isolation region and connected to the first gate structure and the second gate structure.

10. The semiconductor device of claim 9, further comprising:
a backside gate contact positioned below the via.

11. The semiconductor device of claim 10, wherein the backside gate contact connects the first gate structure and the second gate structure to the backside power delivery network.

12. The semiconductor device of claim 9, wherein:
the first contact comprises a backside source/drain contact; and
the second contact comprises a frontside source/drain contact.

13. The semiconductor device of claim 9, wherein the via comprises a conductive material.

14. The semiconductor device of claim 9, wherein the first source/drain region and the second source/drain region are different types of source/drain regions.

15. The semiconductor device of claim 14, wherein the different types of source/drain regions comprise an n-type source/drain region and a p-type source/drain region.

16. The semiconductor device of claim 9, further comprising:
a backside interlayer dielectric layer surrounding side surfaces of the via.

17. A method comprising:
forming an isolation region separating a first gate structure from a second gate structure, wherein the first gate structure is associated with a first source/drain region and the second gate structure is associated with a second source/drain region;
forming a frontside source/drain contact for connecting the second source/drain region to a backside power distribution network to a frontside interconnect layer;
forming a conductive region below the isolation region, wherein the conductive region is connected to the first gate structure and the second gate structure; and
forming a backside contact for connecting the first source/drain region to a backside power distribution network.

18. The method of claim 17, comprising:
forming a dielectric region positioned below the conductive region, wherein the conductive region corresponds to a gate jumper.

19. The method of claim 17, comprising:
forming a backside gate contact connected to the conductive region, wherein the conductive region corresponds to a via.

20. The method of claim 17, wherein the first source/drain region and the second source/drain region are different types of source/drain regions.
